(19) United States
(12) Patent Application Publication
(10) Pub. No.: US 2019/0128967 A1
(43) Pub. Date: May 2, 2019

(54) BATTERY MONITOR SYSTEM

(71) Applicant: PALCELLs Technology, Inc., Milpitas, CA (US)

(72) Inventors: Win Sheng CHENG, Cupertino, CA (US); YiChien HWANG, Fremont, CA (US)

(21) Appl. No.: 16/175,772

(22) Filed: Oct. 30, 2018

Related U.S. Application Data
(60) Provisional application No. 62/579,132, filed on Oct. 30, 2017.

(51) Int. Cl. G01R 31/36; H02J 9/06

(52) U.S. Cl. CPC G01R 31/3648; H02J 9/06; G01R 31/3682; G01R 31/3658; G01R 31/3696

(57) ABSTRACT

A battery backup monitoring system includes a current sensor coupled to each respective battery. An intelligent isolated local charger/inverter is connected to each of the batteries. A battery monitor control board is also connected to each charger/inverter and a respective sensor. The control board includes a microprocessor, multiplexer, I/O control, impedance measurement circuitry and level shifter, ADC and physical memory. Software code is stored in the memory and executed by the processor to control operation of the battery backup system. The microprocessor-controlled system is configured to monitor battery current/voltage/temperature/impedance, battery health/capacity, and battery current over drain (low voltage) for protection of the batteries. The system provides an optimized and easily installed integrated solution for individual battery, multiple batteries or complex battery backup systems for various mission critical applications.

### PRIORITY

This application claims the priority benefit of U.S. Provisional Application No. 62/579,132 filed on Oct. 30, 2017, which is hereby incorporated herein by reference in its entirety.

### FIELD

The present invention relates generally to battery monitoring systems, and more particularly, to systems for monitoring backup batteries and charging components.

### BACKGROUND

Monitoring backup battery systems is challenging. In the battery backup system, batteries are only used when AC power from the grid is not available. In some applications, such as a sump pump, the water level in the water pit also needs to reach the required level to start the backup battery system. Normally the backup batteries are not used to operate the sump pump or perform other similar operations, so they can be easily neglected over time.

Therefore, to ensure a smooth and reliable backup battery system operation, the backup batteries and charger must be monitored regularly. But in some applications, such as a sump pump, most battery systems are not monitored and it is unknown whether the backup batteries will properly function when needed.

One method to address the reliability issue is to use premium brand batteries and replace all the batteries at a regular interval, such as every 1-2 years. Even though most backup batteries are lead-acid type, this regular replacement is costly and produces needless waste. This is magnified even more so when the backup system comprises many batteries, such as in a data center, versus only 1-2 batteries that are used in a typical sump pump system.

For mission critical applications, such as a data center or telecom station, monitoring of the backup batteries is performed via routine manual testing of the backup batteries. Test personnel use manual battery monitor instruments such as an impedance meter or similar instrument to measure the characteristics of each individual battery. Since these measurements are manually performed, the measurements need to be carried through all the batteries. It is very tedious, introduces human error, and presents a safety hazard to the test person since many batteries may be installed in a series string with a high voltage level, or in a parallel configuration with high amperage.

Also, manual measurements are only static, so real dynamic load testing needs to be performed periodically to ensure proper battery operation. Dynamic load testing interferes with the normal system operation, so it must be carefully arranged and scheduled when a partial or full shut down of the facilities can be tolerated to allow for the testing. This creates a hassle and requires large overhead for the battery backup system maintenance people.

There are some battery monitor solutions, but such solutions replace the manual battery measurements with a built-in automatic measurement box connected to each battery. Dynamic load testing is still needed to ensure sufficient confidence level that the backup batteries will perform as intended.

Also, in dynamic load testing, the backup system normally lacks over-drain or low-voltage protection. Thus, the testing may drain the battery to a point below a minimum threshold and result in permanent damage to the battery.

In sump pump applications, when the backup battery is needed to power the pump during a brown-out, in many cases the battery is not monitored and protected, which can likely lead to draining the backup battery to an unrecoverable level.

Therefore, there is a continuing need to provide for improved backup battery monitoring systems and methods.

### SUMMARY

The present invention addresses the above-noted drawbacks of conventional backup battery monitoring and testing systems as completely as possible. The invention provides an efficient and cost effective way to monitor the SoH (State of Health) and SoC (State of Charge) of the battery system as well as the operating status of the charging system to ensure the battery backup system functions normally, and the system can report immediately if the battery and/or charger exhibit a problem.

In some applications such as a sump pump system, the above status information can be provided when requested by the user or when a prompt is determined to be warranted by the system. For example, if a storm is coming or the user will be out of town, the user can use a smartphone software application that interfaces with the battery backup system to inquire as to the battery backup and charging system status and discover the possible issues or achieve peace of mind that the system will operate normally if needed.

The invention provides a simple, built-in, effective and reliable method to automatically monitor the backup battery as well as battery charging system for various battery applications. Once setup, this system can provide automatic monitoring and minimize interference to the normal system operation.

The invention can not only monitor for weak, aging and defective batteries or wiring, but can also monitor for a defective charger and report the defect before it can cause further damage to the batteries due to under charging or not charging the batteries to the proper capacity.

A backup battery monitoring system includes a current sensor coupled to each respective battery. An intelligent isolated local charger/inverter is connected to each of the batteries. A battery monitor control board is also connected to each battery, charger/inverter and a respective current sensor. The control board includes a microprocessor, multiplexer, I/O control, impedance measurement circuitry and level shifter, ADC and physical memory.

Software code is stored in the memory and executed by the processor to control operation of the battery backup system. The microprocessor-controlled system is configured to monitor battery current/voltage/temperature/impedance, battery health/capacity, and battery current over drain (low voltage) during discharging for protection of the batteries. The system provides an optimized and easily installed integrated solution for individual battery, multiple batteries or complex battery backup systems for various mission critical applications.

Provided herein is a smart battery backup charging and monitoring system. The system can include an external load, a battery coupled to the external load, a charger coupled to the battery and to the external load, a switch disposed electrically between the charger and the battery, and a current sensor electrically coupled between the battery and the charger, and between the battery and the external load. A control board, comprising a microcontroller, is coupled to the switch, the charger and the current sensor. The control board can be configured to selectively electrically couple the battery to the charger and to the load, to monitor current flowing from the battery through the current sensor, and to selectively activate the charger. The external load can be electrically coupled to both the battery and the charger so that the external load can be powered by both the charger and battery simultaneously.

The external load can be a sump pump or other similar electric load. The current sensor can be a clamp-on type sensor clamped onto a battery lead or a resistor-type sensor wired in series with a battery lead. Both types of sensors can be provided simultaneously too. The battery can be one cell or more than one cell. An audible alarm, such as a buzzer, can be coupled to the control board to provide an audible indication of a service required condition of the system.

The control board can be configured to interface with a software application running on a smartphone of a user. The control board can be configured to perform a performance test on the battery and store the results of the battery performance test in a memory on the control board. The control board can also be configured to perform a performance test on the charger and store the results of the charger performance test in the memory on the control board. The control board can report a service required condition when either of the battery performance test or the charger performance test produce a result that is outside of a specified limit.

The service required condition can be reported to a smartphone of a user that is running a software application that interfaces with the control board. A wireless module can be coupled to the control board so that the control board can wirelessly communicate with an external computing device such as the smartphone of the user. The control board can also be configured to report a battery backup charging and monitoring system status indication to the smartphone application of the user when promoted by the user via the smartphone application.

The switch, the current sensor, the control board and a wireless transceiver or module can all be integrated into the charger to form a single smart charger.

The control board can be configured to perform a self-test of the battery, the charger, and the external load wiring, and to store results of the self tests in a memory on the control board.

The control board can be configured to open the switch to disconnect the battery from the external load when a state of charge value of the battery drops below a pre-set threshold.

Also provided is a method of operating a smart battery backup charging and monitoring system. Current flow to or from a battery that is connected to an external load and to a charger can be continuously monitored. A switch can be opened to disconnect the battery from the external load when a battery voltage drops below a pre-set threshold. A performance test on the battery and or on the charger can be automatically performed and the results stored in a memory on a control board of the smart battery backup charging and monitoring system. A service required condition can be reported when either of the battery performance test or the charger performance test produces a result that is outside of a specified limit.

At least one of the battery performance test or the charger performance test can be performed when prompted by a user via a software application running on a smartphone of the user that is interfaced with the smart battery backup charging and monitoring system.

Power to the external load can be simultaneously provided from both the battery and the charger.

The above summary is not intended to limit the scope of the invention, or describe each embodiment, aspect, implementation, feature or advantage of the invention. The detailed technology and preferred embodiments for the subject invention are described in the following paragraphs accompanying the appended drawings for people skilled in this field to well appreciate the features of the claimed invention. It is understood that the features mentioned hereinbefore and those to be commented on hereinafter may be used not only in the specified combinations, but also in other combinations or in isolation, without departing from the scope of the present invention.

### BRIEF DESCRIPTION OF THE DRAWINGS

FIG. 1 is a diagram of a battery backup system with battery monitors in accordance with an embodiment of the invention.

FIG. 2 is a diagram of a sump pump battery monitoring system in accordance with an embodiment of the invention.

FIG. 3 is a flow chart of a battery/charger monitoring method in accordance with an embodiment of the invention.

FIG. 4 is a diagram of a backup battery monitoring system in accordance with an embodiment of the invention.

While the invention is amenable to various modifications and alternative forms, specifics thereof have been shown by way of example in the drawings and will be described in detail. It should be understood, however, that the intention is not to limit the invention to the particular example embodiments described. On the contrary, the invention is to cover all modifications, equivalents, and alternatives falling within the scope of the invention as defined by the appended claims.

### DETAILED DESCRIPTION

In the following descriptions, the present invention will be explained with reference to various exemplary embodiments. Nevertheless, these embodiments are not intended to limit the present invention to any specific example, environment, application, or particular implementation described herein. Therefore, descriptions of these example embodiments are only provided for purpose of illustration rather than to limit the present invention.

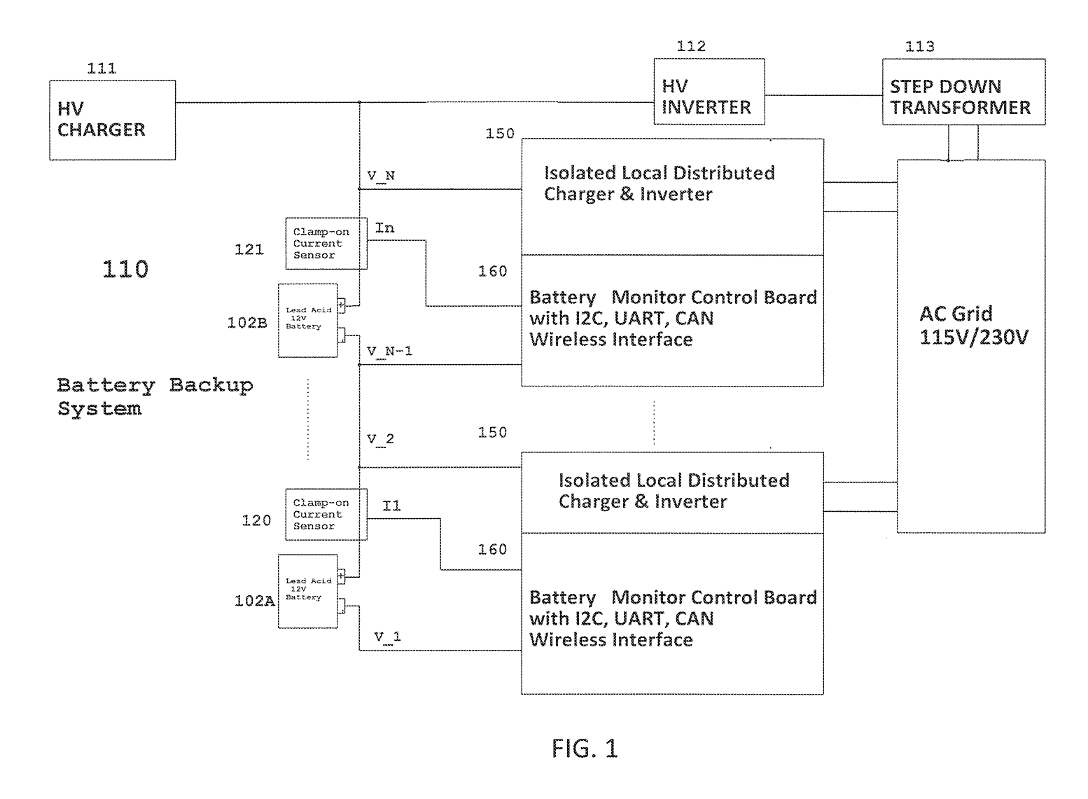

Referring to FIG. 1, a mission critical battery backup system 110 is connected to a high voltage charger 111, which is connected to a high voltage inverter 112, a step down transformer 113 and, ultimately, to the internal AC grid of the building where the backup battery system is located.

The battery backup system 110 includes one or more strings of batteries, although only one string with two batteries is shown in FIG. 1 for simplicity. In FIG. 1, the battery backup system 110 includes a first battery 102A and a second battery 102B. Both batteries are 12V lead-acid type batteries. However, it should be understood that more than two batteries can be used. Alternate battery types can also be used according to the invention, such as various voltages of lead-acid batteries, and lithium-based batteries or battery packs.

A current sensor 120, 121 is coupled to each respective battery 102A, 102B. The current sensors 120, 121 can be a clamp-on type, such as disclosed in U.S. Patent Application Pub. No. 2017/0315156 A1, entitled CURRENT SENSOR AND BATTERY CURRENT MONITORING SYSTEM, which is fully incorporated herein by reference in its entirety as part of this application.

An intelligent isolated local charger/inverter 150 is connected to each of the batteries 102A, 102B. The inverter is grid-tied and can be connected to the internal AC grid or other type of loads.

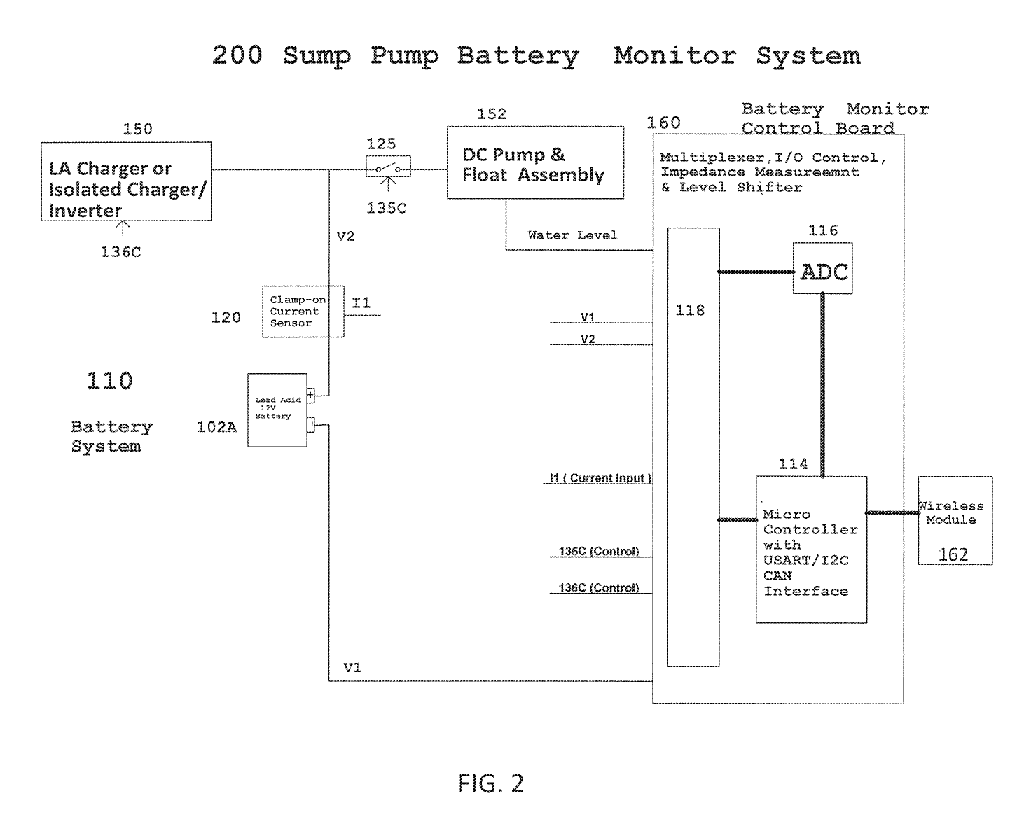

A battery monitor control board 160 is also connected to each charger/inverter 150 and a respective sensor 120 or 121. As shown in FIG. 2, the control board 160 includes a microprocessor or microcontroller 114, multiplexer, I/O control, impedance measurement circuitry and level shifter 118, analog-to-digital converter (ADC) 116, and physical memory. Software code is stored in the memory and executed by the microprocessor to control and monitor the operation of the battery backup system 110.

The battery monitor control board 160 is configured to monitor battery current/voltage/temperature, battery health/capacity/impedance, and battery current over drain (low voltage) for protection of the batteries. This system of the control board 160 and charger/inverter 150 provides an optimized and easily installed integrated solution for an individual battery, multiple batteries or complex battery backup systems for various mission critical applications.

The battery monitoring control board 160 via the current sensors 120, 121 continuously monitors the charging voltage, current and internal impedance of the monitored battery or batteries during charging. The monitoring includes the voltage and current effect from both the HV (high voltage) charger and the local isolated local charger/inverter.

During monitoring of discharging of the battery, the isolated local inverter/charger 150 can be operated by the microprocessor's 114 programming to perform a short term full, or partial single, or multiple battery load generation, similar to dynamic load tests.

The microprocessor 114 is programmed to report any voltage, current and impedance deviations from pre-defined normal operation ranges based on the battery condition during the charging and discharging processes. The report is sent via wired or wireless transmission to a cloud computing system or to a designated remote computing device, such as a smart phone via an app. A wireless module 162 can be coupled to the microprocessor 114 to accomplish this transmission. The user's app will alert the user to the deviation noted by the processor 114. The report can also be sent to appropriate technical persons so that repairs can be quickly made.

All the testing data of the voltage, current, temperature, charging time and internal impedance from the measurement circuitry can be compared by the processor 114 with built-in internal data ranges and uploaded to the cloud or remote computer system where it will be stored in memory for further processing and trend analysis. For example, the remote computer system can store the measurement data to a data base and compare the current data with data from past healthy battery testing results to reveal any trends or data discrepancies.

After the simulated discharging load testing, a charger function can be performed and simulated voltage, current, temperature, impedance results can be measured and uploaded. All the data discussed herein can be used by the remote computing system to determine a battery SoH (status of health) as well as verify the normal function of the charger.

The measurements described herein are performed and tracked regularly after a new battery or batteries are installed. The ongoing data is uploaded back to the cloud/server and closely monitored with past battery data. So the battery/discharging records will be closely monitored under predetermined charging/discharging condition and time intervals. In case a variation is found, a warning to the user will be sent as noted above.

The full or partial current load testing is a high current testing, which will not be performed frequently, but instead only on an on-demand basis. The control board 160 will monitor regularly the low current load testing for the proper function of the charging connection elements 111, 112, 113 and batteries 102A and 102B. The full load testing results and impedance will be monitored using the HV inverter 112 tied into the AC grid as the load. The load current can be varied by the setup of the local inverter 150.

The local charger/inverter 150 will be mainly used to refurbish the load testing drainage to ensure the battery 102A, 102B will be fully charged and properly in float mode if a lead acid battery is used. The charging current and floating voltage/current can also be monitored by the microprocessor 114 to ensure the proper operation and to report any deviations that may occur.

The full load testing can be performed at a preprogrammed time and set so that only one battery or battery set is tested at one time. Thus, the testing can be carried out automatically and no dynamic load shutdown is required.

If an AC grid power outage, which can be detected immediately by the current sensor, occurs during a testing period, the testing can be suspended and the battery undergoing testing can be returned to normal service so that it functions in its normal backup role as the full/partial load test is performed only in short periods and only one battery in a string is selected.

Referring to FIG. 2, a schematic for a sump battery monitor system 200 is shown. The inverter load 150 from FIG. 1 is replaced with a real pump load 152 and all the other measurements and data processing remain the same.

A switch 125 between the pump 152 and battery 102A selectively energizes the pump 152 via control signal 135C and 136C from the battery monitor control board 160. The charger/inverter 150 is controllably coupled to the control board via control connection 136C to disable the charger's output when this requirement is needed during testing. The charger/inverter 150 can be simplified to be only a charger to reduce the cost.

A wireless module 162 is shown connected to the microcontroller. The wireless module 162 provides the communication to/from the cloud or remote computing system. The wireless protocol can be any conventional wireless means, including Wi-Fi, Cellular, Bluetooth, etc.

This invention provides an optimized, reliable and automatic solution for battery/charger monitoring without interrupting the battery backup system in the mission critical environment where the conventional solution cannot deliver. It also can identify the charger quality and status, and report any issues of not only the local charger but also the general high voltage charger.

This invention can also be used in any battery pack solution, in any backup battery, or battery system in a ship, RV, EV car, vehicle start-up battery, golf cart, and many more. In some applications, the application circuitry can be simplified to meet the requirements.

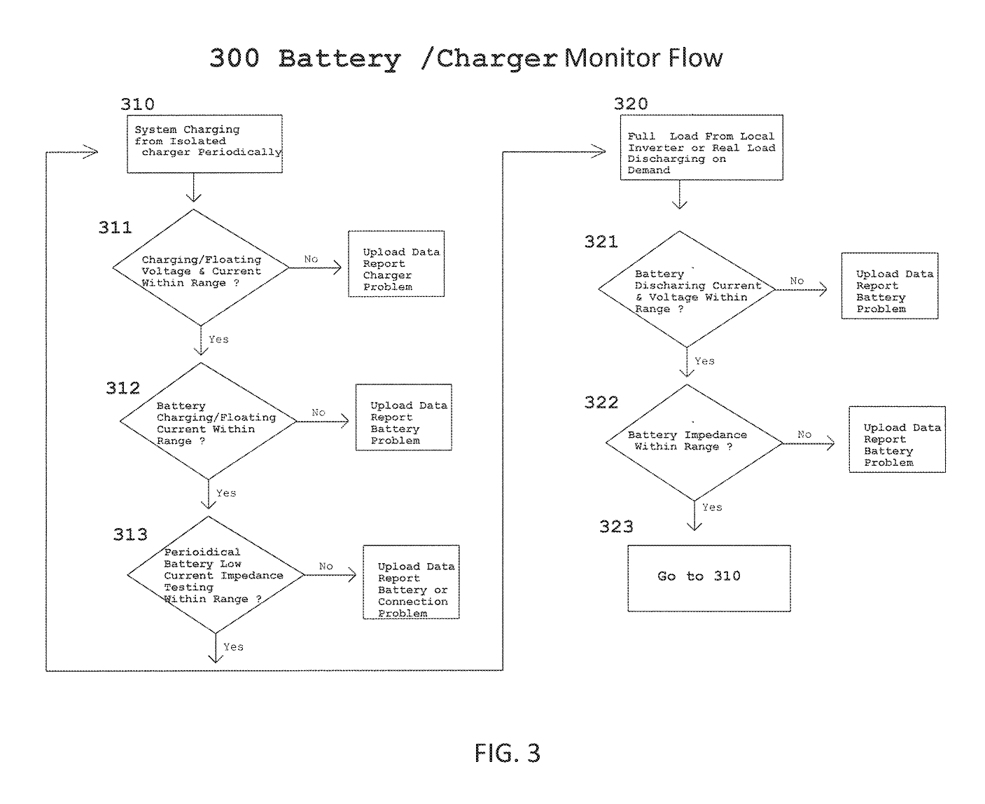

Referring to FIG. 3, a flowchart 300 for a battery charger monitoring process is shown. The battery system is normally charged periodically when discharging is done earlier from the charger flow 310. The monitor system monitors to determine: if the charger's charging/float voltage and current are within a predetermined range 311; if the battery's charge/float current is within a predetermined range 312; and whether a periodic test of the battery's impedance is within a predetermined range. An out of range condition is reported to the remote computing system as noted in FIG. 3.

FIG. 3 also shows the evaluation of the battery's discharge for a full load from the local inverter or real load on demand 320. The battery discharge and current are monitored 321, and battery impedance is monitored 321, to determine whether they are within a predetermined range. An out of range condition is reported to the remote computing system as noted in FIG. 3.

The monitoring cycle then repeats 323 back to step 310.

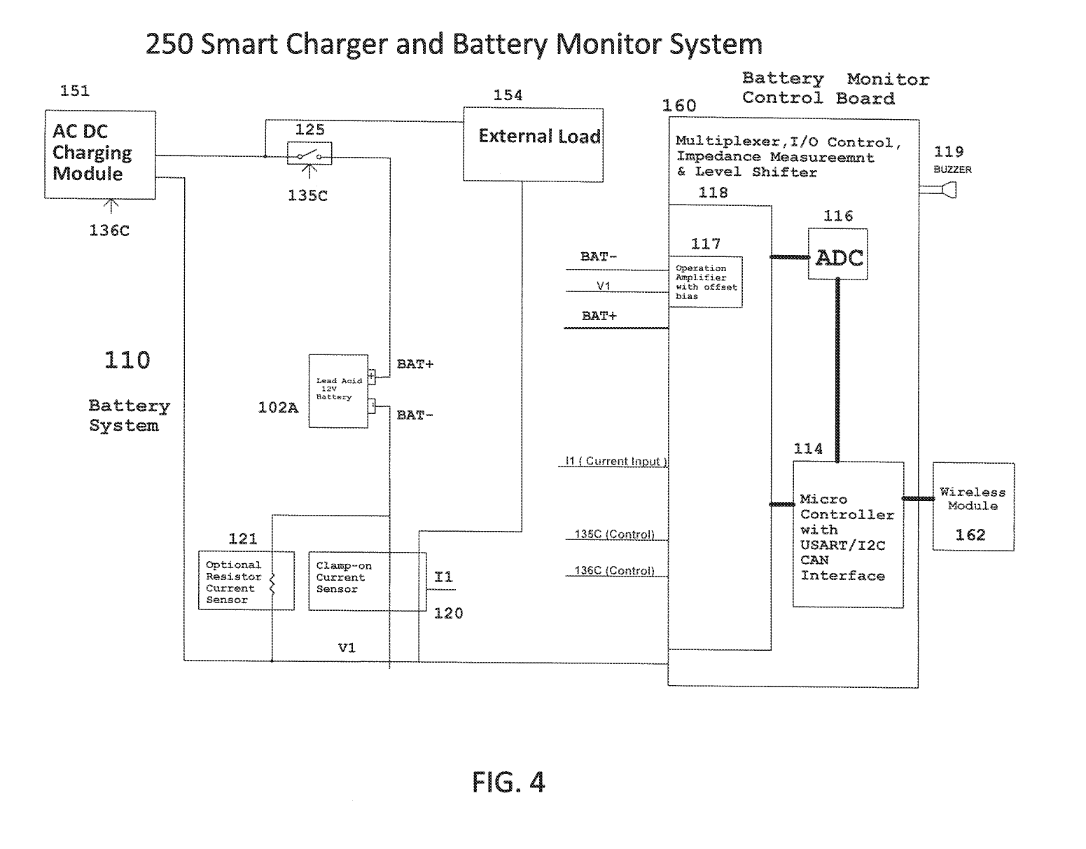

Referring to FIG. 4, a schematic for a smart charger and battery monitor system 250 is shown. As compared to the schematic of FIG. 2, the switch 125 is located in the battery 102A line and does not disconnect the external load (e.g. pump) from the charging module 150. The battery 102A is connected to and provides operational power to the battery monitor control board 160. The impedance measurement circuitry and level shifter 118 now includes an operation amplifier with offset bias 117. The external load 154 is connected to a new location. A resistor current sensor 121 is also shown in parallel to the clamp-on current sensor 120. A buzzer 119 or audible alarm is also coupled to the control board to provide an audible indication of a condition requiring human attention.

The alterations as compared to FIG. 2 still allow the charger 151 to charge the battery 102A with over charge protection without the additional power switch 125 being located inside the charger module 151. Protection against over drain of the battery and under voltage of battery discharging is maintained.

The schematic of FIG. 4 monitors charging and discharging of current flow to/from the battery 102A with either of the clamp-on current sensor 120 or a low-cost current resistor sensor 121. Both sensors could also be used together. The clamp-on current sensor 120 can monitor the battery charging current, battery discharging current and total discharging current when discharging from both charger 151 and battery 102A. The low-cost current sensor 121 can only monitor battery charging current, battery discharging current and battery discharging current when discharging from both charger 151 and battery 102A.

The system 250 according to the schematic of FIG. 4 also supplements the charger's 151 output with power supplied from the battery 102A. This arrangement reduces the power output requirements of the charger 151 because some of the supplied power comes from battery 102A. Thus, the charger can be designed with a lower power output specification, which results in reduced heat output, smaller overall size and a simpler and more reliable charger.

The system 250 according to the schematic of FIG. 4 also does not need built-in power switches located within the charger 151 to protect the charger during battery charging. This reduces the power dissipation of the power switches that would otherwise be needed inside of the charger 151. As a result, efficiency of charging and discharging is improved, and related switch control circuitry can be eliminated.

Note that the control switch 125, current sensors 120, 121, control board 160 and the wireless module 162 can be integrated into the charger 151 as a single smart charger to simplify the wiring and connection to the external load and battery.

Control signal 136C, which is isolated, allows selective disabling and enabling of the charger module 151. This allows extensive system self diagnostic testing. By enabling the switch 125 through the control signal 135C for a short period time, roughly fixed current is supplied from battery 102A to power the load 154. By measuring the voltage drop of the battery 102A and current flow through current sensors 120, 121 and knowing the wiring and characteristics of the battery 102A, the proper connection of wiring to and from the battery 102A can be determined. The same determinations can also can be performed during the charging process given that the charging voltage, current and charger status can be known.

The measured result or self test results of battery, charger, pump and system wiring are stored in the memory on the control board 160. A smartphone software app stored in the memory of the smartphone and executed by the smartphone's processor interfaces wirelessly with the control board 160 through wireless module 162 to allow the user to check the monitored smart charger/battery system. The control board 160 can also automatically push system status changes to the user's smartphone app wirelessly so that alerts can be displayed on the user's smart phone. Thus, the user can take immediate action in case some system components need servicing or immediate action.

The user also can use the app to request that the control board prompt the user of approaching storms that could pose a grid power loss or flooding. The user can then prompt the system for status information or the status information can be automatically pushed to the user's smartphone.

An additional feature and benefit of the present system is that the user can prompt the control board 160 for system data whenever the user desires or when an error is detected, such as indicated by a beep tone from buzzer 119. The user, thus, can use their app on a smartphone or other networked computing device to inquire of the battery system status and proactively handle any noted issues before an error is reported. This avoids the need for a cloud computing service to collect and process the battery system data, which can be interrupted in the case of a brown-out situation for the grid because the wireless router may not be powered to transmit the data to the cloud in such instance.

Phone numbers and contact information for service technicians can be stored inside the smartphone app software. Thus, when an issue with the system is detected, the user can press the phone number to call or send notice of the error message, including the system information and history, to the service technician. This streamlines the maintenance procedure and proper service action can be taken without unnecessary delay during the reporting process. The control board can also be configured to automatically initiate the service request mentioned above without user input as soon as the error condition arises.

While the invention has been described in connection with what is presently considered to be the most practical and preferred embodiments, it will be apparent to those of ordinary skill in the art that the invention is not to be limited to the disclosed embodiments. It will be readily apparent to those of ordinary skill in the art that many modifications and equivalent arrangements can be made thereof without departing from the spirit and scope of the present disclosure, such scope to be accorded the broadest interpretation of the appended claims so as to encompass all equivalent structures and products. Moreover, features or aspects of various example embodiments may be mixed and matched (even if such combination is not explicitly described herein) without departing from the scope of the invention.

What is claimed is:

1. A smart battery backup charging and monitoring system, comprising:
an external load;
a battery coupled to the external load;
a charger coupled to the battery and to the external load;
a switch disposed electrically between the charger and the battery;
a current sensor electrically coupled between the battery and the charger, and between the battery and the external load;
a control board, comprising a microcontroller, the control board coupled to the switch, the charger and the current sensor, the control board configured to selectively electrically couple the battery to the charger and to the load, to monitor current flowing from the battery through the current sensor, and to selectively activate the charger,
wherein the external load is electrically coupled to both the battery and the charger so that the external load can be powered by both the charger and battery simultaneously.

2. The smart battery backup charging and monitoring system of claim 1, wherein the external load is a sump pump.

3. The smart battery backup charging and monitoring system of claim 1, wherein the current sensor is a clamp-on type sensor clamped onto a battery lead.

4. The smart battery backup charging and monitoring system of claim 1, wherein the current sensor is a resistor-type sensor wired in series with a battery lead.

5. The smart battery backup charging and monitoring system of claim 1, wherein the current sensor comprises a clamp-on type sensor clamped onto a battery lead and a resistor-type sensor wired in series with a battery lead.

6. The smart battery backup charging and monitoring system of claim 1, wherein the battery comprises a plurality of battery cells.

7. The smart battery backup charging and monitoring system of claim 1, further comprising an audible alarm coupled to the control board.

8. The smart battery backup charging and monitoring system of claim 1, wherein the control board is configured to interface with a software application running on a smartphone of a user.

9. The smart battery backup charging and monitoring system of claim 1, wherein the control board is configured to perform a performance test on the battery and store the results of the battery performance test in a memory on the control board.

10. The smart battery backup charging and monitoring system of claim 9, wherein the control board is configured to perform a performance test on the charger and store the results of the charger performance test in the memory on the control board.

11. The smart battery backup charging and monitoring system of claim 10, wherein the control board is configured to report a service required condition when either of the battery performance test or the charger performance test produce a result that is outside of a specified limit.

12. The smart battery backup charging and monitoring system of claim 11, wherein the service required condition is reported to a smartphone of a user that is running a software application that interfaces with the control board.

13. The smart battery backup charging and monitoring system of claim 1, further comprising a wireless module coupled to the control board such that the control board can wirelessly communicate with an external computing device.

14. The smart battery backup charging and monitoring system of claim 1, wherein the control board is configured to interface with a software application running on a smartphone of a user, and the control board is configured to report a battery backup charging and monitoring system status indication to the smartphone application of the user when prompted by the user via the smartphone application.

15. The smart battery backup charging and monitoring system of claim 1, wherein the switch, the current sensor, the control board and a wireless transceiver are all integrated into the charger to form a single smart charger.

16. The smart battery backup charging and monitoring system of claim 1, wherein the control board is configured to perform a self-test of the battery, the charger, and the external load wiring, and to store results of the self tests in a memory on the control board.

17. The smart battery backup charging and monitoring system of claim 1, wherein the control board is configured to open the switch to disconnect the battery from the external load when a voltage level of the battery drops below a pre-set threshold.

18. A method of operating a smart battery backup charging and monitoring system, the method comprising:
continuously monitoring a current flow to or from a battery that is connected to an external load and to a charger;
opening a switch to disconnect the battery from the external load or the charger when a voltage value of the battery drops below or rises above a pre-set threshold;
performing automatically a performance test on the battery and storing the results of the battery performance test in a memory on a control board of the smart battery backup charging and monitoring system;
performing automatically a performance test on the charger and storing the results of the charger performance test in the memory on the control board of the smart battery backup charging and monitoring system;
reporting a service required condition when either of the battery performance test or the charger performance test produces a result that is outside of a specified limit.

19. The method of claim 18, further comprising performing at least one of the battery performance test or the charger performance test when prompted by a user via a software application running on a smartphone of the user that is interfaced with the smart battery backup charging and monitoring system.

20. The method of claim 19, further comprising providing power to the external load simultaneously from both the battery and the charger.
